(19) United States
(12) Patent Application Publication
(10) Pub. No.: US 2024/0079850 A1
(43) Pub. Date: Mar. 7, 2024

(54) SEMICONDUCTOR DEVICE AND MANUFACTURING METHOD THEREOF

(71) Applicants: HON HAI PRECISION INDUSTRY CO., LTD., New Taipei City (TW); National Yang Ming Chiao Tung University, Hsinchu City (TW)

(72) Inventors: Wen-Cheng HSU, New Taipei City (TW); Yu-Heng HONG, New Taipei City (TW); Yao-Wei HUANG, New Taipei City (TW); Kuo-Bin HONG, New Taipei City (TW); Hao-Chung KUO, New Taipei City (TW)

(21) Appl. No.: 18/147,006

(22) Filed: Dec. 28, 2022

(30) Foreign Application Priority Data
Sep. 7, 2022 (TW) 111133961

(51) Int. Cl. H01S 5/042; H01S 5/028; H01S 5/11

(52) U.S. Cl. CPC H01S 5/0421; H01S 5/0282; H01S 5/04256; H01S 5/11

(57) ABSTRACT

A semiconductor device includes a first contact layer, a second contact layer, an active layer, a photonic crystal layer, a passivation layer, a first electrode and a second electrode. The first contact layer has a first surface and a second surface opposite to each other. Microstructures are located on the second surface. The second contact layer is located below the first surface. The active layer is located between the first contact layer and the second contact layer. The photonic crystal layer is located between the active layer and the second contact layer. The passivation layer is located on the second contact layer. The first electrode is located on the passivation layer and is electrically connected the first surface of the first contact layer. The second electrode is located on the passivation layer and is electrically connected to the second contact layer.

### RELATED APPLICATION

This application claims priority to Taiwan Application Serial Number 111133961, filed Sep. 7, 2022, which is herein incorporated by reference in its entirety.

### BACKGROUND

### Field of Invention

The present disclosure relates to a semiconductor device and a manufacturing method of the semiconductor device.

### Description of Related Art

In general, semiconductor devices applied to projectors may include active and passive devices. For example, packaging processes may be performed to assemble the active devices and the passive devices together. Traditional passive devices are optical lenses, which utilize thickness or surface curvature at different locations of the optical lenses to produce diffraction effects. However, the semiconductor process may not precisely control the thickness or the surface curvature of each position of the optical lenses, thus reducing the diffraction effect of the optical lenses. In addition, a vertical cavity surface emitting laser (VCSEL) may be used as a light source in conventional semiconductor devices. Due to the small luminous area of the VCSEL, the luminous power of the semiconductor devices is low, which affects the overall optical effect of the semiconductor devices.

### SUMMARY

An aspect of the present disclosure is related to a semiconductor device.

According to an embodiment of the present disclosure, a semiconductor device includes a first contact layer, a second contact layer, an active layer, a photonic crystal layer, a passivation layer, a first electrode and a second electrode. The first contact layer has a first surface and a second surface opposite to the first surface. The second surface has a plurality of microstructures. The second contact layer is located below the first surface of the first contact layer. The active layer is located between the first contact layer and the second contact layer. The photonic crystal layer is located between the active layer and the second contact layer. The passivation layer is located on the second contact layer. The first electrode is located on the passivation layer and electrically connected to the first surface of the first contact layer. The second electrode is located on the passivation layer and electrically connected to the second contact layer.

In an embodiment of the present disclosure, the first contact layer is one of an n-type contact layer and a p-type contact layer, and the second contact layer is the other one of the n-type contact layer and the p-type contact layer.

In an embodiment of the present disclosure, the semiconductor device further includes a first cladding layer and a second cladding layer. The first cladding layer is located between the first contact layer and the active layer. The second cladding layer is located between the second contact layer and the photonic crystal layer.

In an embodiment of the present disclosure, the first contact layer, the first cladding layer, the active layer, the photonic crystal layer, the second cladding layer and the second contact layer are made of homogeneous materials.

In an embodiment of the present disclosure, the second electrode is in contact with the second contact layer, and a width of the second electrode in contact with the second contact layer is less than a width of the photonic crystal layer.

In an embodiment of the present disclosure, each of the microstructures has a bottom and a protruding portion. The protruding portions are disposed on the bottoms. A projected area of the protruding portions on the bottoms is less than a projected area of the bottoms.

In an embodiment of the present disclosure, the bottoms are square or hexagonal, and the protruding portions are circle, square, rectangular, or a combination thereof.

An aspect of the present disclosure is related to a manufacturing method of a semiconductor device.

According to an embodiment of the present disclosure, a manufacturing method of a semiconductor device includes: sequentially forming a first cladding layer, a first guiding layer, an active layer, a second guiding layer, a photonic crystal layer, a second cladding layer and a second contact layer on a first surface of a first contact layer; forming a trench in the first cladding layer, the first guiding layer, the active layer, the second guiding layer, the photonic crystal layer, the second cladding layer and the second contact layer; forming a passivation layer in the trench and on the second contact layer, wherein the passivation layer has a first opening and a second opening, the first contact layer is exposed from the first opening, and the second contact layer is exposed from the second opening; forming a first electrode in the first opening and on the passivation layer such that the first electrode is electrically connected to the first contact layer in the first opening; forming a second electrode in the second opening and on the passivation layer such that the second electrode is electrically connected to the second contact layer in the second opening; and forming a plurality of microstructures on a second surface opposite to the first surface of the first contact layer.

In an embodiment of the present disclosure, forming the microstructures on the second surface further includes: disposing a hard mask layer on the second surface of the first contact layer; forming an electron blocking layer on the hard mask layer, wherein the electron blocking layer has a plurality of patterns; etching the hard mask layer and the first contact layer according to the patterns of the electron blocking layer to form the microstructures; and removing the hard mask layer and the electron blocking layer.

In an embodiment of the present disclosure, the method further includes: coating a protective layer on the passivation layer, the first electrode and the second electrode after forming the second electrode; planarizing the protective layer; etching the protective layer on the first electrode and the second electrode such that the first electrode and the second electrode are exposed from the protective layer.

In an embodiment of the present disclosure, forming the second electrode in the second opening and on the passivation layer further includes: forming a photoresist layer on the first electrode and the passivation layer, wherein the second opening of the passivation layer is exposed from the photoresist layer; forming a metal layer in the second opening and on the photoresist layer; patterning the metal layer to form the second electrode; and removing the photoresist layer.

In an embodiment of the present disclosure, forming the metal layer in the second opening and on the photoresist layer is performed such that a width of the metal layer in the second opening is less than a width of the photonic crystal layer.

An aspect of the present disclosure is related to a semiconductor device.

According to an embodiment of the present disclosure, a semiconductor device includes a first contact layer, a second contact layer, a first guiding layer, a second guiding layer, a photonic crystal layer, a passivation layer, a first electrode and a second electrode. The first contact layer has a first surface and a second surface opposite to the first surface. The second surface has a plurality of microstructures. The second contact layer is located below the first surface of the first contact layer. The first guiding layer is located between the first contact layer and the second contact layer. The second guiding layer is located between the first guiding layer and the second contact layer. The photonic crystal layer is located between the second guiding layer and the second contact layer. The passivation layer is located on the second contact layer. The first electrode is located on the passivation layer and electrically connected to the first surface of the first contact layer. The second electrode is located on the passivation layer and electrically connected to the second contact layer.

In an embodiment of the present disclosure, the first contact layer is one of an n-type contact layer and a p-type contact layer, and the second contact layer is the other one of the n-type contact layer and the p-type contact layer.

In an embodiment of the present disclosure, the semiconductor device further includes a first cladding layer. The first cladding layer is located between the first contact layer and the first guiding layer.

In an embodiment of the present disclosure, the semiconductor device further includes a second cladding layer. The second cladding layer is located between the first cladding layer and the second contact layer.

In an embodiment of the present disclosure, the first contact layer, the first cladding layer, the first guiding layer, the second guiding layer, the photonic crystal layer, the second cladding layer and the second contact layer are made of homogeneous materials.

In an embodiment of the present disclosure, the second electrode is in contact with the second contact layer, and a width of the second electrode in contact with the second contact layer is less than a width of the photonic crystal layer.

In an embodiment of the present disclosure, each of the microstructures has a bottom and a protruding portion. The protruding portions are disposed on the bottoms. A projected area of the protruding portions on the bottoms is less than a projected area of the bottoms.

In an embodiment of the present disclosure, the bottoms are square or hexagonal, and the protruding portions are circle, square, rectangular, or a combination thereof.

In the embodiments of the present disclosure, traditional passive devices may be replaced by the microstructures of the first contact layer of the semiconductor device, so an overall volume and a thickness of the semiconductor device may be reduced, which is advantageous to miniaturization. In addition, the microstructures integrated on the second surface of the first contact layer by semiconductor processes may avoid yield problems and reduce manufacturing costs from back-end packaging processes. In addition, both the first electrode and the second electrode of the semiconductor device are located below the first surface of the first contact layer and located on the passivation layer. Coplanar design of the first electrode and the second electrode may reduce the number of alignments in the process and shorten the manufacturing time of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a bottom view of a semiconductor device according to one embodiment of the present disclosure.

FIG. 1B illustrates a cross-sectional view of the semiconductor device in FIG. 1A along a line segment 1B-1B.

FIG. 2A to FIG. 2F illustrate stereoscopic views of microstructures according to some embodiments of the present disclosure.

FIG. 3A and FIG. 3B illustrate schematic views of speckle patterns according to some embodiment of the present disclosure.

FIG. 4 illustrates a flow chart of a manufacturing method of semiconductor device according to one embodiment of the present disclosure.

FIG. 5 to FIG. 23 illustrate cross-sectional views at various steps of a manufacturing method of a semiconductor device according to another embodiment of the present disclosure.

FIG. 24 to FIG. 29 illustrate cross-sectional views at various steps of a manufacturing method of a semiconductor device according to the other embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

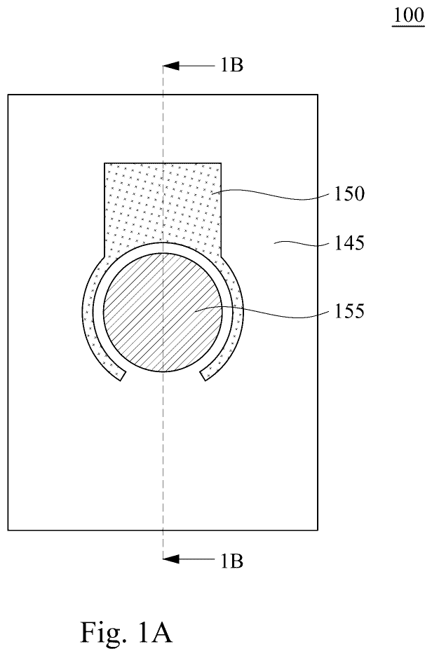

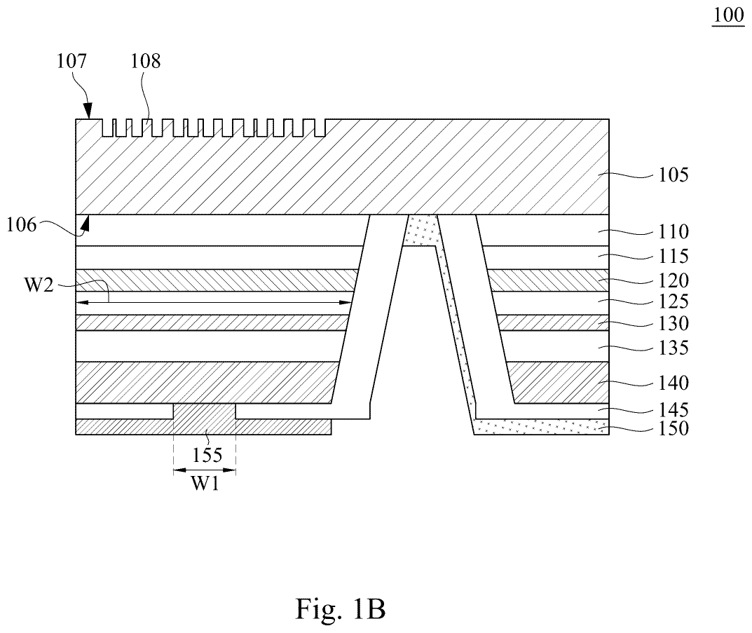

FIG. 1A illustrates a bottom view of a semiconductor device 100 according to one embodiment of the present disclosure. FIG. 1B illustrates a cross-sectional view of the semiconductor device 100 in FIG. 1A along a line segment 1B-1B. For example, the semiconductor device 100 may be applied to a sensing system of a mobile phone and a related short-range stereo depth sensing system. Referring to both FIG. 1A and FIG. 1B, the semiconductor device 100 includes a first contact layer 105, an active layer 120, a photonic crystal layer 130, a second contact layer 140, a passivation layer 145, a first electrode 150 and a second electrode 155. The first contact layer 105 has a first surface 106 and a second surface 107 opposite to the first surface 106. The second surface 107 of the first contact layer 105 has microstructures 108 thereon. The second contact layer 140 may be located below the first surface 106 of the first contact layer 105. In some embodiments, the first contact layer 105 may be one of an n-type contact layer and a p-type contact layer, and the second contact layer 140 may be the other one of the n-type contact layer and the p-type contact layer. A plurality of layers may be located between the first contact layer 105 and the second contact layer 140. The active layer 120 may be located between the first contact layer 105 and the second contact layer 140. The active layer 120 may be a quantum well and is configured to emit light. The photonic crystal layer 130 may be located between the active layer 120 and the second contact layer 140. The photonic crystal layer 130 may be a resonant cavity of the active layer 120 emitting light. The passivation layer 145 may be located on the second contact layer 140. The first electrode 150 may be located on the passivation layer 145 and electrically connected to the first surface 106 of the first contact layer 105. The second electrode 155 may be located on the passivation layer 145 and electrically connected to the second contact layer 140.

In some embodiments, the semiconductor device 100 further includes a first cladding layer 110, a first guiding layer 115, a second guiding layer 125, and a second cladding layer 135. The first cladding layer 110 may be located between the first contact layer 105 and the first guiding layer 115. The first guiding layer 115 may be located between the first cladding layer 110 and the active layer 120. The second guide layer 125 may be located between the active layer 120 and the photonic crystal layer 130. The second cladding layer 135 may be located between the photonic crystal layer 130 and the second contact layer 140. For example, the semiconductor device 100 may be a structure of an epitaxial wafer including the first contact layer 105, the first cladding layer 110, the first guiding layer 115, the active layer 120, the second guiding layer 125, the photonic crystal layer 130, the second cladding layer 135 and the second contact layer 140.

In some embodiments, the first contact layer 105, the first cladding layer 110, the first guiding layer 115, the active layer 120, the second guiding layer 125, the photonic crystal layer 130, the second cladding layer 135 and the second contact layer 140 may be regarded as a structure of a photonic crystal surface emitting laser (PCSEL). For example, the photonic crystal surface emitting lasers (PCSELs) may provide effects of small divergence angles and large area. The second surface 107 of the first contact layer 105 having the microstructure 108 may be regarded as a meta-surface, and the meta-surface may be a light-emitting surface of the photonic crystal surface emitting laser (PCSEL). In addition, the first contact layer 105, the first cladding layer 110, the first guiding layer 115, the active layer 120, the second guiding layer 125, the photonic crystal layer 130, the second cladding layer 135, and the second contact layer 140 may be made of homogeneous material. That is, interfaces between two of the first contact layer 105, the first cladding layer 110, the first guiding layer 115, the active layer 120, the second guiding layer 125, the photonic crystal layer 130, the second cladding layer 135 and the second contact layer 140 may be homogeneously bonded, which may avoid optical reflection and scattering caused by discontinuous heterogeneous interfaces. Therefore, an optical effect of the semiconductor device 100 may be improved.

Particularly, traditional passive devices may be replaced by the microstructures 108 of the first contact layer 105 of the semiconductor device 100, so an overall volume and a thickness of the semiconductor device 100 may be reduced, which is advantageous to miniaturization. In addition, the microstructures 108 integrated on the second surface 107 of the first contact layer 105 by semiconductor processes may avoid yield problems and reduce manufacturing costs from back-end packaging processes. In addition, both the first electrode 150 and the second electrode 155 of the semiconductor device 100 are located below the first surface 106 of the first contact layer 105 and located on the passivation layer 145. Coplanar design of the first electrode 150 and the second electrode 155 may reduce the number of alignments in the process and shorten the manufacturing time of the semiconductor device 100.

In some embodiments, the semiconductor device 100 further includes a protective layer 160. The protective layer 160 may cover a portion of the first electrode 150 and the second electrode 155. The first electrode 150 and the second electrode 155 not covered by the protective layer 160 may be electrically connected to electrodes of an external substrate. In addition, the second electrode 155 is in contact with the second contact layer 140, and a width W1 of the second electrode 155 in contact with the second contact layer 140 is less than a width W2 of the photonic crystal layer 130. That is, a current confinement aperture (the width W1) of the semiconductor device 100 is less than the width W2 of the photonic crystal layer 130. Such design may enhance the optical effect of the semiconductor device 100.

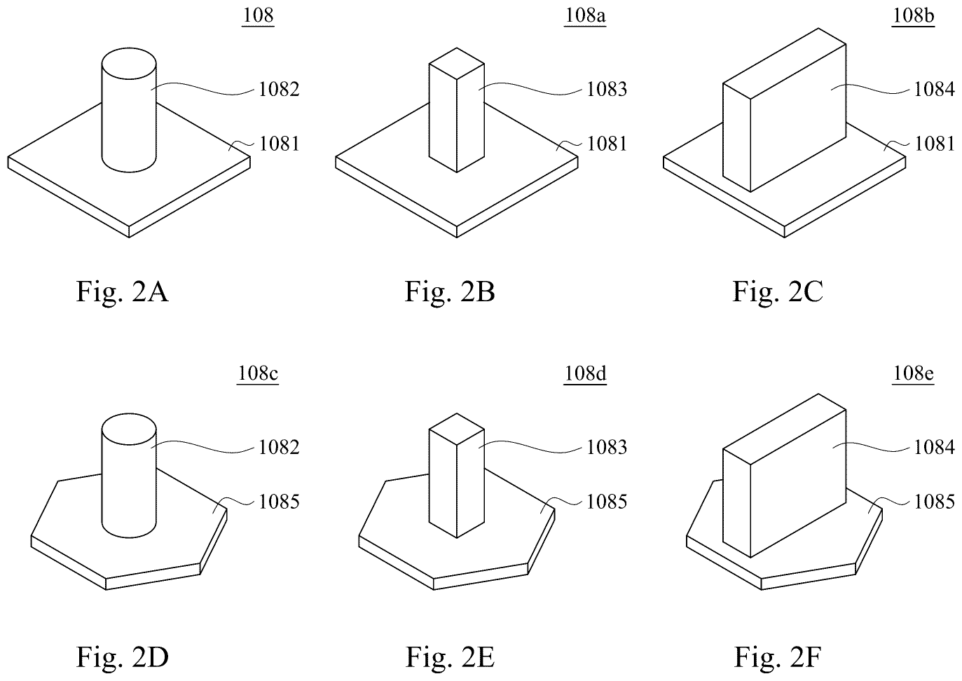

FIG. 2A to FIG. 2F illustrate stereoscopic views of microstructures 108, 108a, 108b, 108c, 108d and 108e according to some embodiments of the present disclosure. The microstructure 108 has a bottom portion 1081 and a convex portion 1082 extending upward from the bottom portion 1081. That is, the convex portion 1082 is disposed on the bottom portion 1081. It is to be noted that a projected area of the convex portion 1082 on the bottom portion 1081 is less than a projected area of the bottom portion 1081. In this embodiment, the bottom portion 1081 may be a square, and the convex portion 1082 may be a circle. The difference between the microstructure 108a of FIG. 2B and the embodiment of FIG. 2A is that a convex portion 1083 of the microstructure 108a is square. The difference between the microstructure 108b of FIG. 2C and the embodiment of FIG. 2A is that a convex portion 1084 of the microstructure 108b is a rectangle. The difference between the microstructure 108c of FIG. 2D and the embodiment of FIG. 2A is that a bottom 1085 of the microstructure 108c is hexagonal. The difference between the microstructure 108d of FIG. 2E and the embodiment of FIG. 2B is that the bottom 1085 of the microstructure 108d is hexagonal. The difference between the microstructure 108e of FIG. 2F and the embodiment of FIG. 2C is that the bottom 1085 of the microstructure 108e is hexagonal.

In some embodiments, shape of the microstructure 108 may be designed according to computer generated holography (CGH). For example, the computer generated holography may determine a structure period and a structure size of the microstructure 108 according to phase propagation ratio or geometric phase. A structure size of phase change may be obtained through a system look-up table. In addition, the computer generated hologram (CGH) may select the structure period and the size in the corresponding system look-up table according to a formula of optical lenses to combine the microstructures 108 with a function of lenses. Compared with conventional optical lenses, the semiconductor process may control and fabricate the microstructures 108 with the function of the lenses, which may improve limitations of using the lenses. For example, the microstructures 108 may expand an angular range of optical diffraction.

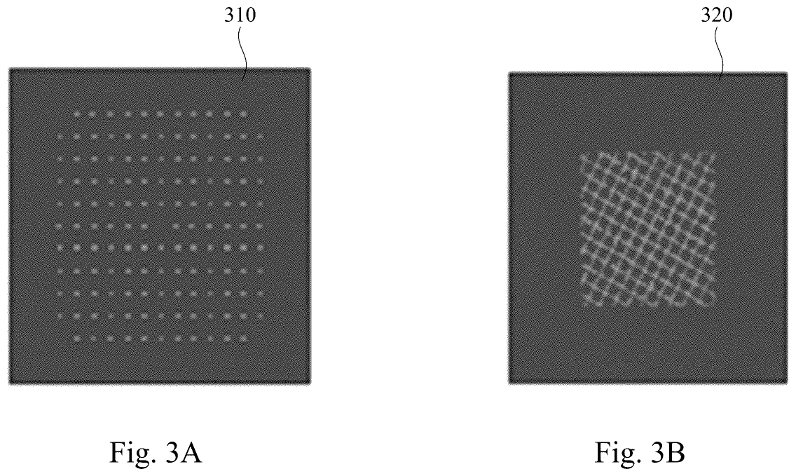

FIG. 3A and FIG. 3B illustrate schematic views of speckle patterns 310 and 320 according to some embodiment of the present disclosure. Referring to both FIG. 3A and FIG. 3B, the semiconductor device 100 may generate a speckle pattern 310 of a dot array in a far field. Alternatively, the semiconductor device 100 may design the microstructure 108 (see FIG. 1B) according to different sensing methods to generate a speckle pattern 320 of mesh array. Compared with conventional optical lenses, the semiconductor device 100 may generate the speckle pattern 310 and the speckle pattern 320 by changing phase distribution of the microstructure 108, which may provide customized effects.

In the following description, a manufacturing method of a semiconductor device will be described. It is to be noted that the connection relationship of the aforementioned elements will not be repeated.

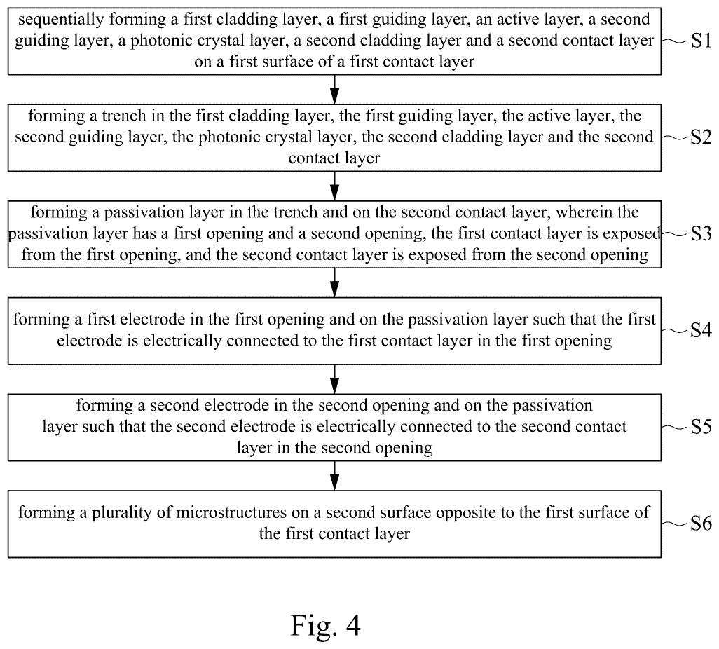

FIG. 4 illustrates a flow chart of a manufacturing method of a semiconductor device according to one embodiment of the present disclosure. The manufacturing method of the semiconductor device includes steps as outlined below. In step S1, a first cladding layer, a first guiding layer, an active layer, a second guiding layer, a photonic crystal layer, a second cladding layer and a second contact layer are sequentially formed on a first surface of a first contact layer. In step S2, a trench is formed in the first cladding layer, the first guiding layer, the active layer, the second guiding layer, the photonic crystal layer, the second cladding layer and the second contact layer. In step S3, a passivation layer is formed in the trench and on the second contact layer, wherein the passivation layer has a first opening and a second opening, the first contact layer is exposed from the first opening, and the second contact layer is exposed from the second opening. In step S4, a first electrode is formed in the first opening and on the passivation layer such that the first electrode is electrically connected to the first contact layer in the first opening. In step S5, a second electrode is formed in the second opening and on the passivation layer such that the second electrode is electrically connected to the second contact layer in the second opening. In step S6, a plurality of microstructures are formed on a second surface opposite to the first surface of the first contact layer. In the following description, the aforementioned steps will be described in detail.

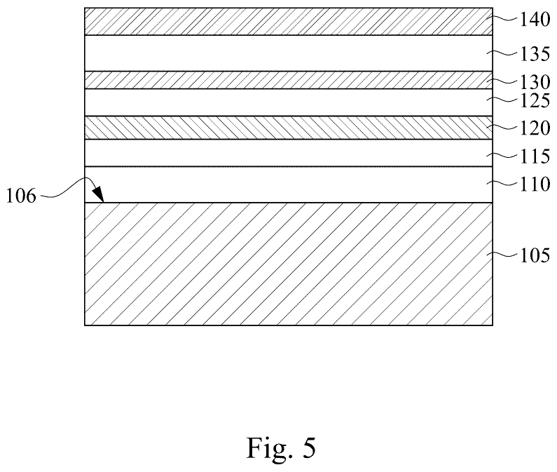

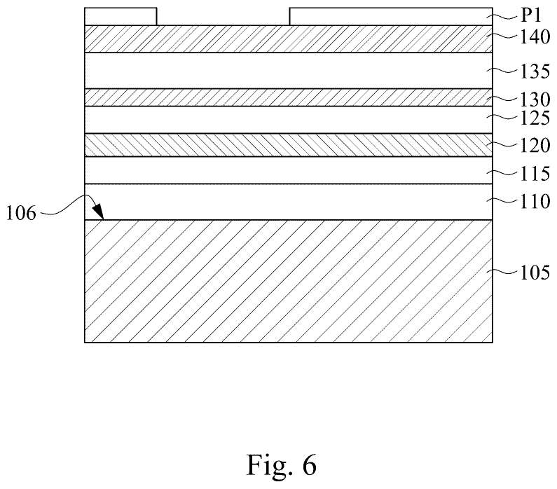

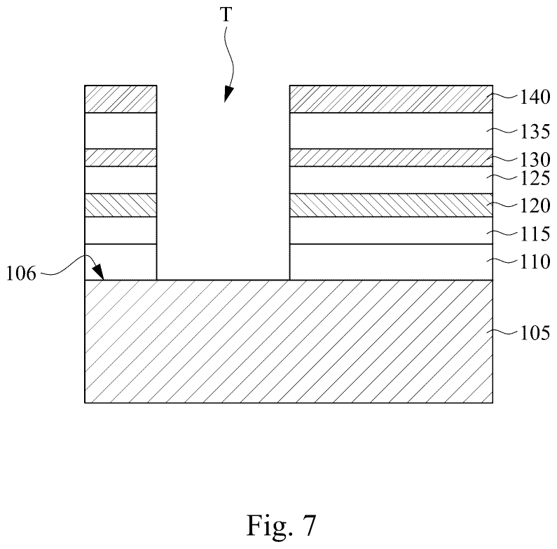

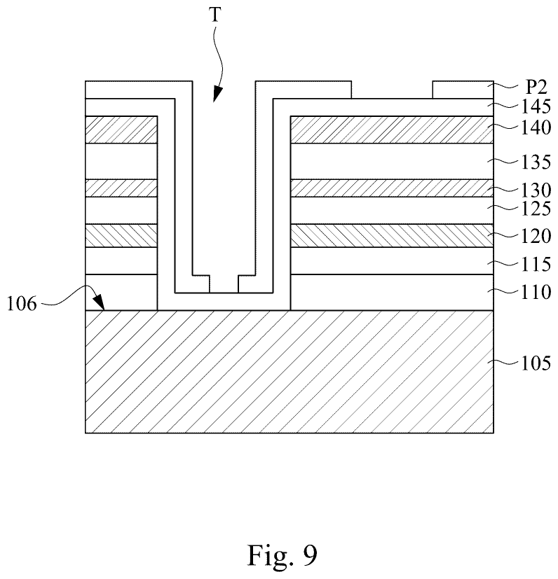

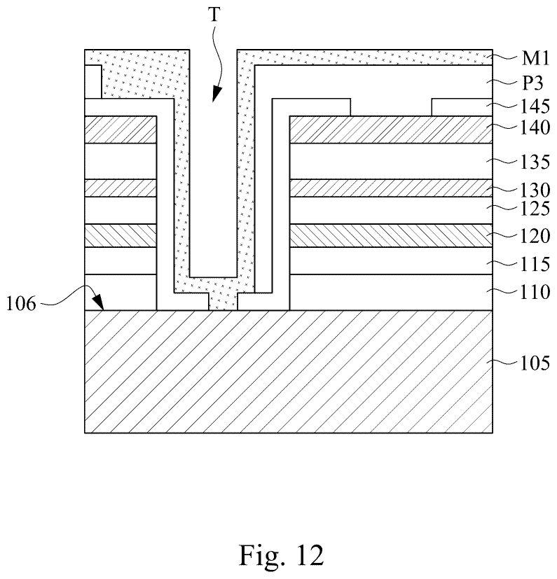

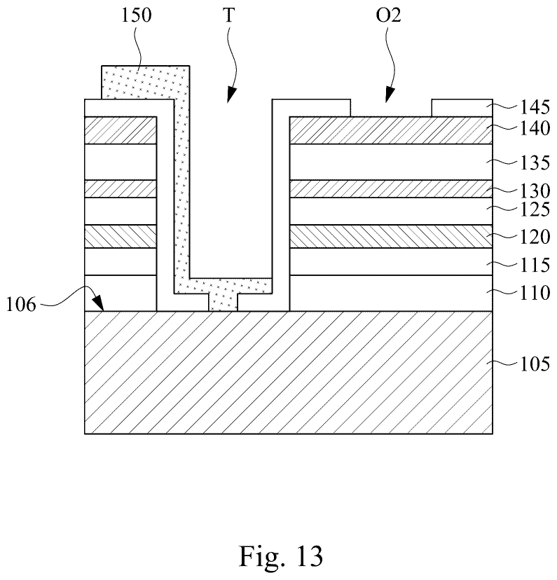

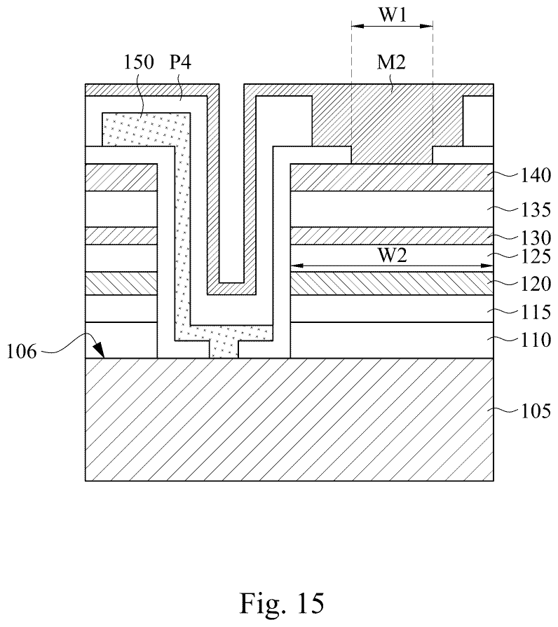

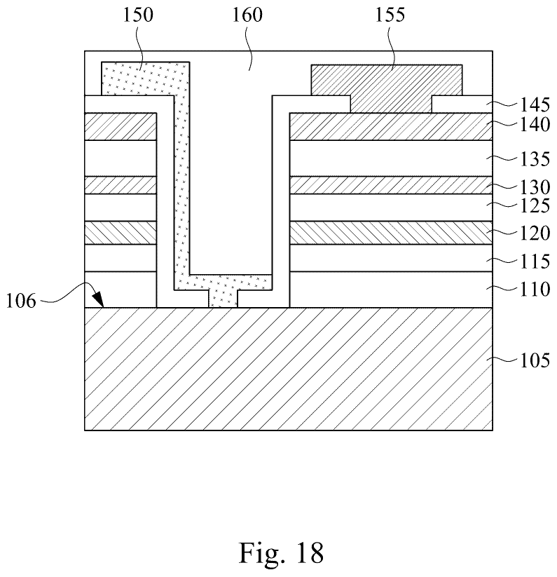

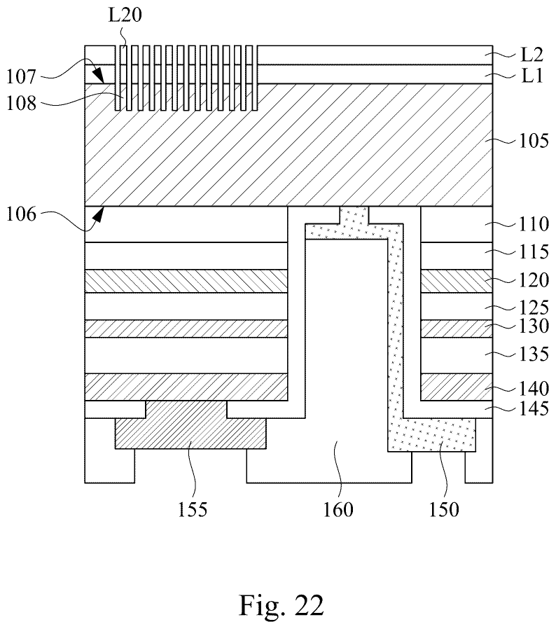

FIG. 5 to FIG. 23 illustrate cross-sectional views at various steps of a manufacturing method of a semiconductor device according to another embodiment of the present disclosure. Referring FIG. 5 to FIG. 7, first, the first cladding layer 110, the first guiding layer 115, the active layer 120, the second guiding layer 125, the photonic crystal layer 130, the second cladding layer 135 and the second contact layer 140 may be sequentially formed on the first surface 106 of the first contact layer 105. Next, a photoresist layer P1 may be disposed on the second contact layer 140. Next, the second contact layer 140 not covered by the photoresist layer P1 may be etched such that a trench T is formed in the first cladding layer 110, the first guiding layer 115, the active layer 120, the second guiding layer 125, the photonic crystal layer 130, the second cladding layer 135 and the second contact layer 140. In this way, the first surface 106 of the first contact layer 105 may be exposed from the trench T. After the trench T is formed, the photoresist layer P1 may be removed to form a structure shown in FIG. 7.

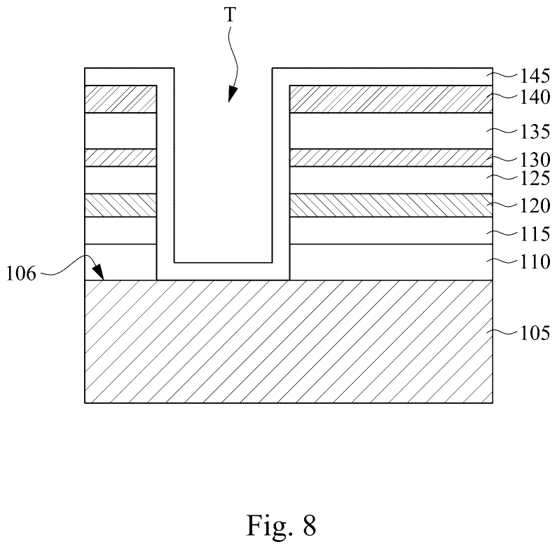

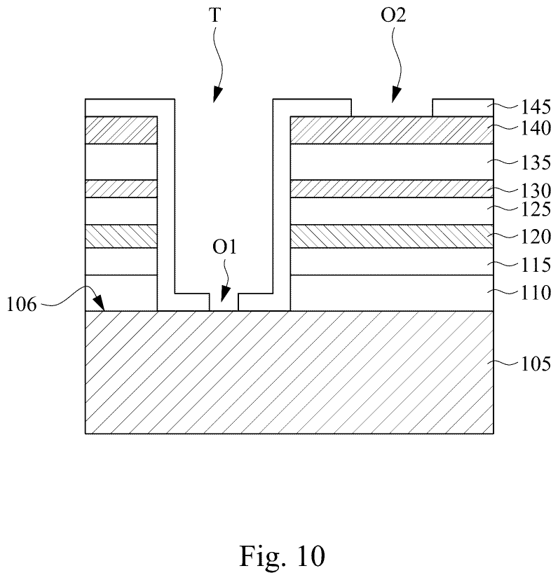

Referring to FIG. 8 to FIG. 10, next, the passivation layer 145 may be formed in the trench T and on the second contact layer 140. After the passivation layer 145 is formed, a photoresist layer P2 may be disposed on the passivation layer 145. Next, the passivation layer 145 not covered by the photoresist layer P2 may be etched such that the passivation layer 145 has a first opening O1 and a second opening O2. The first surface 106 of the first contact layer 105 is exposed from the first opening O1, and the second contact layer 140 is exposed from the second opening O2. Next, the photoresist layer P2 may be removed to form the structure shown in FIG. 10.

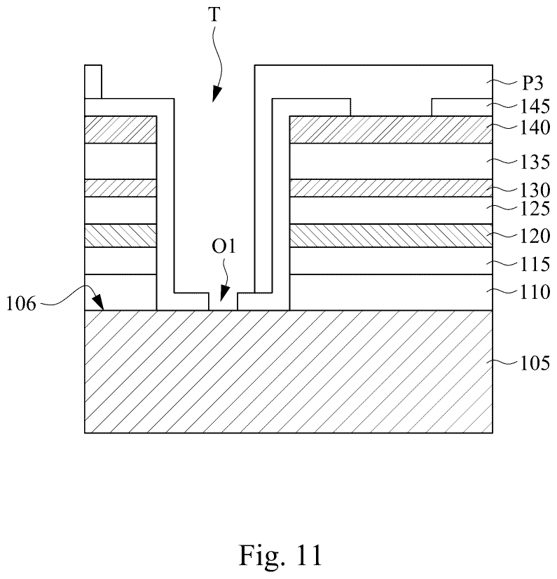

Referring to FIG. 11 to FIG. 13, after the passivation layer 145 having the first opening O1 and the second opening O2 is formed, a photoresist layer P3 may be disposed on the passivation layer 145. The photoresist layer P3 does not cover the first opening O1. Next, a metal layer M1 may be formed in the first opening O1 and on the passivation layer 145. For example, the metal layer M1 may be formed by a flip chip process. Next, the metal layer M1 may be patterned to form a first electrode 150, and the first electrode 150 is electrically connected to the first contact layer 105 in the first opening O1. Next, the photoresist layer P3 may be removed to form the structure shown in FIG. 13.

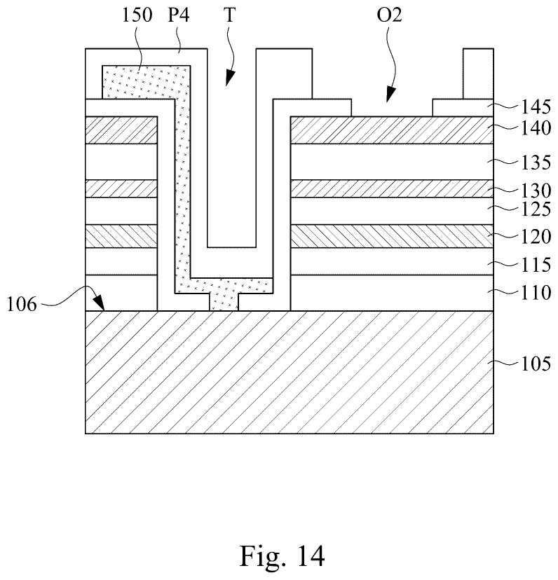

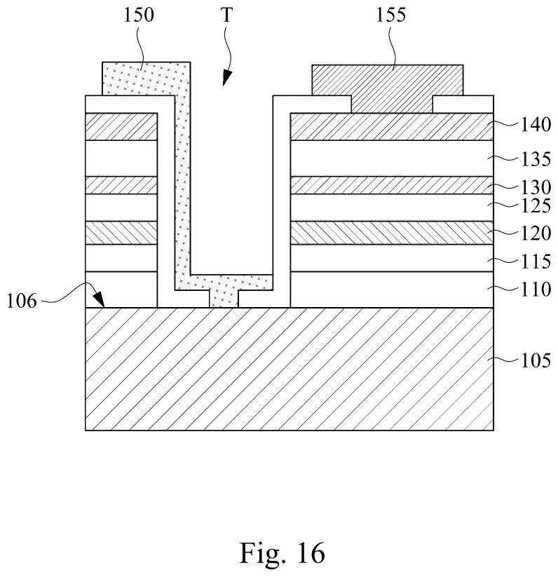

Referring to FIG. 14 to FIG. 16, after the first electrode 150 is formed, a patterned photoresist layer P4 may be formed on the first electrode 150 and the passivation layer 145. The second opening O2 of the passivation layer 145 is exposed from the photoresist layer P4. Next, a metal layer M2 may be formed in the second opening O2 and on the photoresist layer P4. For example, the metal layer M2 may be formed by a flip chip process. In some embodiments, the width W1 of the metal layer M2 formed in the second opening O2 is less than the width W2 of the photonic crystal layer 130. Next, the metal layer M2 may be patterned to form the second electrode 155, and the second electrode 155 is electrically connected to the second contact layer 140 in the second opening O2. The second electrode 155 may improve a heat dissipation effect of the active layer 120 and may prevent a high working temperature of the active layer 120. Next, the photoresist layer P4 may be removed to form the structure shown in FIG. 16.

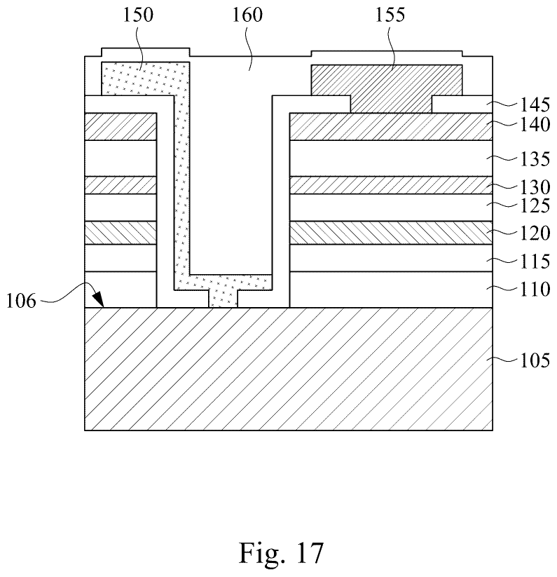

Referring to FIG. 17 to FIG. 19, after the second electrode 155 is formed, the protective layer 160 may be coated on the passivation layer 145, the first electrode 150 and the second electrode 155. Next, the protective layer 160 may be planarized. The protective layer 160 located on the first electrode 150 and the second electrode 155 may be etched such that the first electrode 150 and the second electrode 155 are exposed from the protective layer 160. The first electrode 150 and the second electrode 155 not covered by the protective layer 160 may be electrically connected to electrodes of an external substrate.

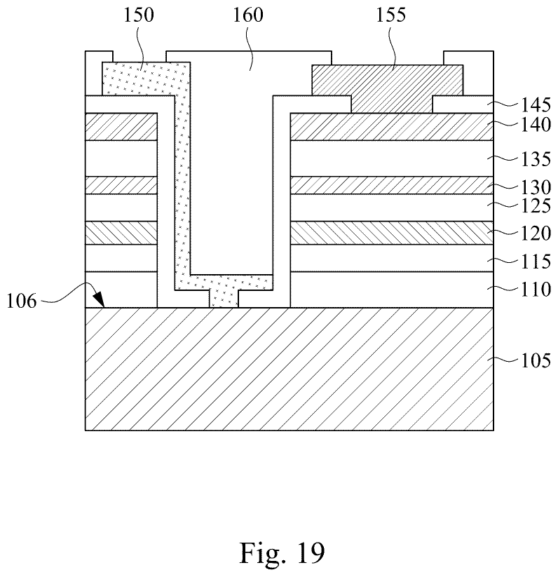

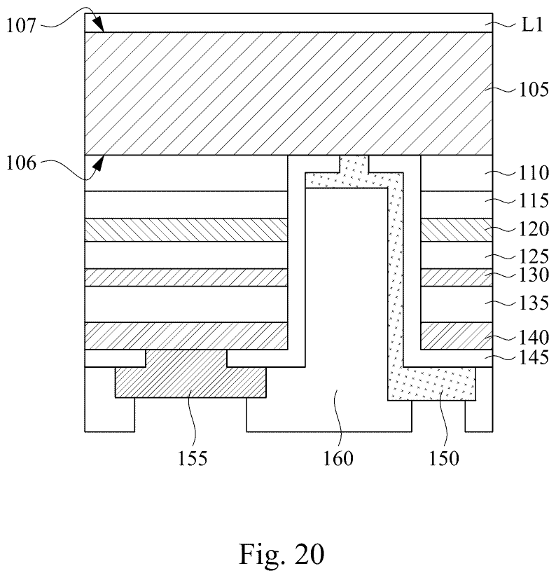

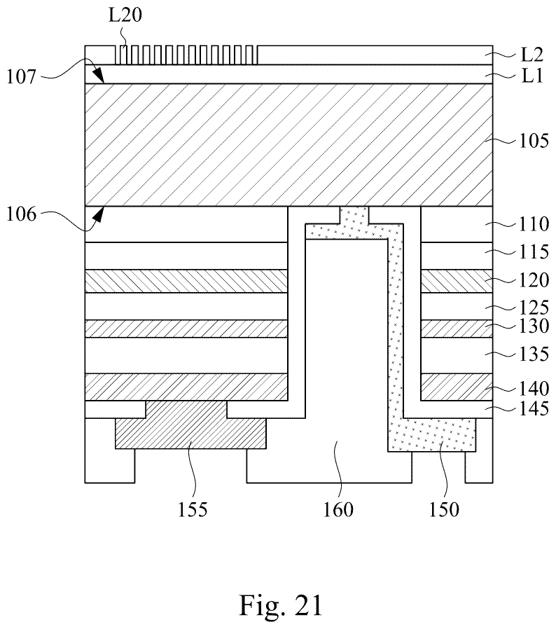

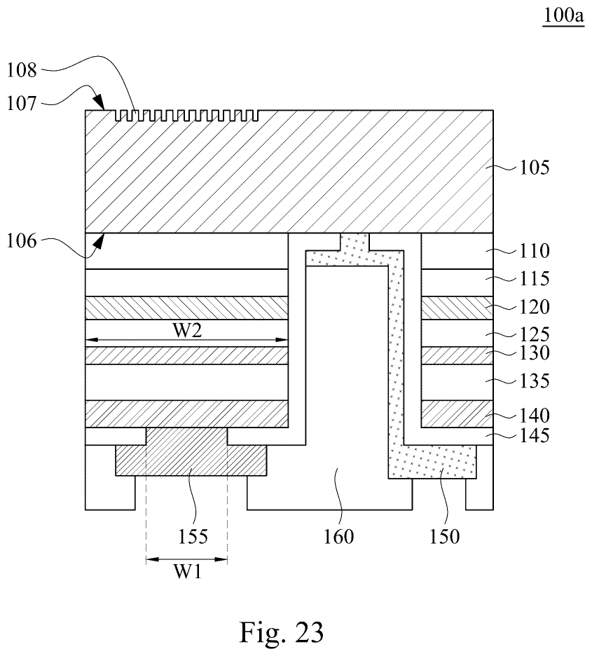

Referring to FIG. 20 to FIG. 23, next, the structure of FIG. 19 may be reversed, and a hard mask layer L1 may be disposed on the second surface 107 of the first contact layer 105 opposite to the first surface 106. Next, an electron blocking layer L2 may be formed on the hard mask layer L1. The electron blocking layer L2 has a plurality of patterns L20. Next, the hard mask layer L1 and the first contact layer 105 may be etched according to the patterns L20 of the electron blocking layer L2 to form the microstructure 108 on the second surface 107 of the first contact layer 105. Next, the hard mask layer L1 and the electron blocking layer L2 may be removed to form a semiconductor device 100a shown in FIG. 23. The traditional passive devices may be replaced by the microstructure 108 of the semiconductor device 100a, so an overall volume and a thickness of the semiconductor device 100a may be reduced, which is beneficial to miniaturization.

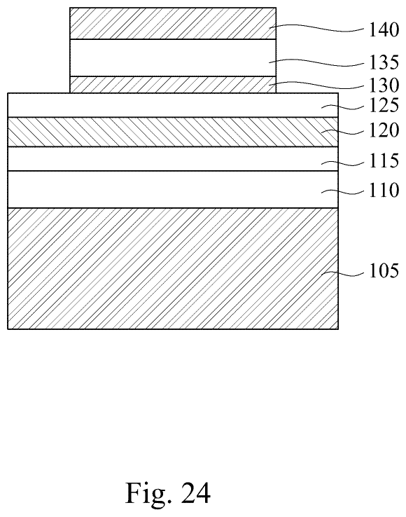

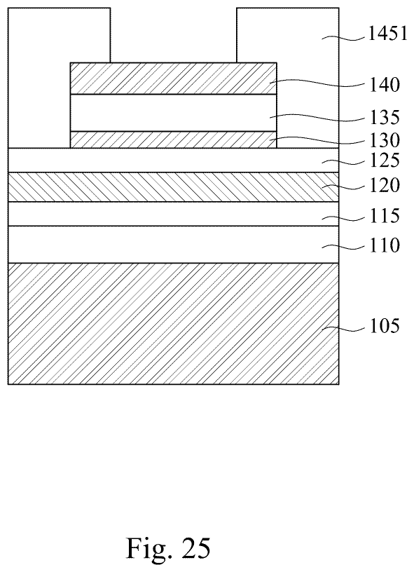

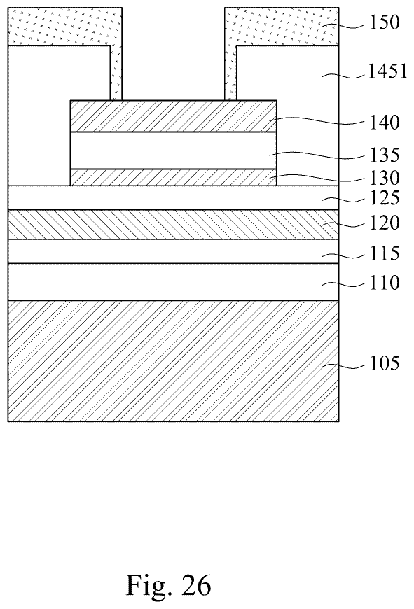

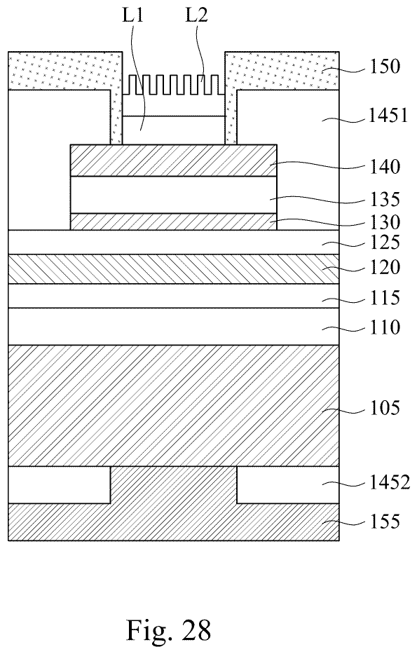

FIG. 24 to FIG. 29 illustrate cross-sectional views at various steps of a manufacturing method of a semiconductor device according to the other embodiment of the present disclosure. Referring to FIG. 24 to FIG. 26, first, the photonic crystal layer 130, the second cladding layer 135 and the second contact layer 140 may be etched. After the photonic crystal layer 130, the second cladding layer 135 and the second contact layer 140 are etched, a first passivation layer 1451 may be formed on the second guiding layer 125 and the second contact layer 140. The first passivation layer 1451 partially covers the second contact layer 140. After the first passivation layer 1451 is formed, the first electrode 150 may be formed on the second contact layer 140 and the first passivation layer 1451 such that the first electrode 150 covers the first passivation layer 1451 and partially covers the second contact layer 140.

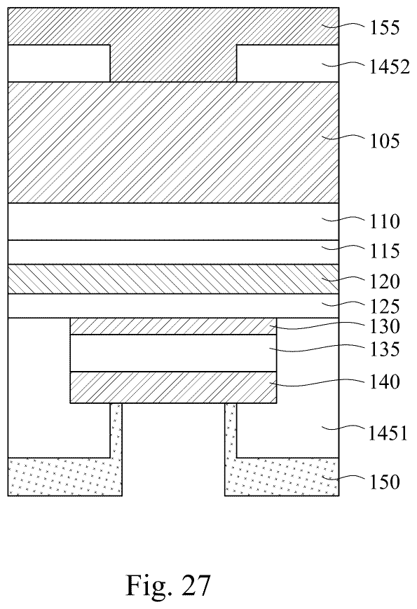

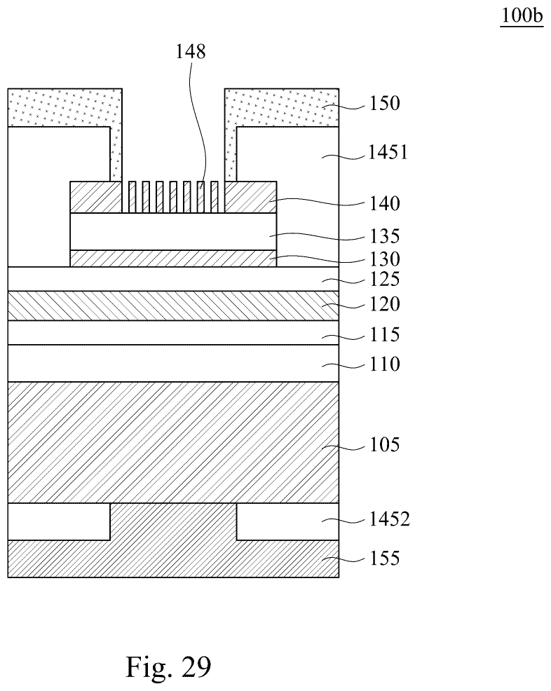

Referring to FIG. 27 to FIG. 29, after the first electrode 150 is formed, a structure may be turned over 180 degrees (upside down) and a second passivation layer 1452 may be formed on the first contact layer 105. After the second passivation layer 1452 is formed, the second electrode 155 may be formed on the first contact layer 105 and the second passivation layer 1452 such that the second electrode 155 covers the first contact layer 105 and the second passivation layer 1452. Next, the structure may be turned over again, and the hard mask layer L1 is formed on the second contact layer 140 and in the first electrode 150. After the hard mask layer L1 is formed, the electron blocking layer L2 may be formed on the hard mask layer L1. After the electron blocking layer L2 is formed, the electron blocking layer L2, the hard mask layer L1 and the second contact layer 140 may be etched such that the second contact layer 140 has a microstructure 148. Next, the hard mask layer L1 and the electron blocking layer L2 may be removed to form a semiconductor device 100b as shown in FIG. 29. Traditional passive devices may be replaced by the microstructure 148 of the semiconductor device 100b, so an overall volume and a thickness of the semiconductor device 100b may be reduced, which is beneficial for miniaturization.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first contact layer having a first surface and a second surface opposite to the first surface, wherein the second surface has a plurality of microstructures;
a second contact layer located below the first surface of the first contact layer;
an active layer located between the first contact layer and the second contact layer;
a photonic crystal layer located between the active layer and the second contact layer;
a passivation layer located on the second contact layer;
a first electrode located on the passivation layer and electrically connected to the first surface of the first contact layer; and
a second electrode located on the passivation layer and electrically connected to the second contact layer.

2. The semiconductor device of claim 1, wherein the first contact layer is one of an n-type contact layer and a p-type contact layer, and the second contact layer is the other one of the n-type contact layer and the p-type contact layer.

3. The semiconductor device of claim 1, further comprising:
a first cladding layer located between the first contact layer and the active layer; and
a second cladding layer located between the second contact layer and the photonic crystal layer.

4. The semiconductor device of claim 3, wherein the first contact layer, the first cladding layer, the active layer, the photonic crystal layer, the second cladding layer and the second contact layer are made of homogeneous materials.

5. The semiconductor device of claim 1, wherein the second electrode is in contact with the second contact layer, and a width of the second electrode in contact with the second contact layer is less than a width of the photonic crystal layer.

6. The semiconductor device of claim 1, wherein each of the microstructures has a bottom and a protruding portion, wherein the protruding portions are disposed on the bottoms, and a projected area of the protruding portions on the bottoms is less than a projected area of the bottoms.

7. The semiconductor device of claim 6, wherein the bottoms are square or hexagonal, and the protruding portions are circle, square, rectangular, or a combination thereof.

8. A manufacturing method of a semiconductor device, comprising:
sequentially forming a first cladding layer, a first guiding layer, an active layer, a second guiding layer, a photonic crystal layer, a second cladding layer and a second contact layer on a first surface of a first contact layer;
forming a trench in the first cladding layer, the first guiding layer, the active layer, the second guiding layer, the photonic crystal layer, the second cladding layer and the second contact layer;
forming a passivation layer in the trench and on the second contact layer, wherein the passivation layer has a first opening and a second opening, the first contact layer is exposed from the first opening, and the second contact layer is exposed from the second opening;
forming a first electrode in the first opening and on the passivation layer such that the first electrode is electrically connected to the first contact layer in the first opening;
forming a second electrode in the second opening and on the passivation layer such that the second electrode is electrically connected to the second contact layer in the second opening; and
forming a plurality of microstructures on a second surface opposite to the first surface of the first contact layer.

9. The method of claim 8, wherein forming the microstructures on the second surface further comprises:
disposing a hard mask layer on the second surface of the first contact layer;
forming an electron blocking layer on the hard mask layer, wherein the electron blocking layer has a plurality of patterns;
etching the hard mask layer and the first contact layer according to the patterns of the electron blocking layer to form the microstructures; and
removing the hard mask layer and the electron blocking layer.

10. The method of claim 8, further comprising:
coating a protective layer on the passivation layer, the first electrode and the second electrode after forming the second electrode;
planarizing the protective layer; and
etching the protective layer on the first electrode and the second electrode such that the first electrode and the second electrode are exposed from the protective layer.

11. The method of claim 8, wherein forming the second electrode in the second opening and on the passivation layer further comprises:
forming a photoresist layer on the first electrode and the passivation layer, wherein the second opening of the passivation layer is exposed from the photoresist layer;
forming a metal layer in the second opening and on the photoresist layer;
patterning the metal layer to form the second electrode; and
removing the photoresist layer.

12. The method of claim 11, wherein forming the metal layer in the second opening and on the photoresist layer is performed such that a width of the metal layer in the second opening is less than a width of the photonic crystal layer.

13. A semiconductor device, comprising:
a first contact layer having a first surface and a second surface opposite to the first surface, wherein the second surface has a plurality of microstructures;
a second contact layer located below the first surface of the first contact layer;
a first guiding layer located between the first contact layer and the second contact layer;
a second guiding layer located between the first guiding layer and the second contact layer;
a photonic crystal layer located between the second guiding layer and the second contact layer;
a passivation layer located on the second contact layer;
a first electrode located on the passivation layer and electrically connected to the first surface of the first contact layer; and
a second electrode located on the passivation layer and electrically connected to the second contact layer.

14. The semiconductor device of claim 13, wherein the first contact layer is one of an n-type contact layer and a p-type contact layer, and the second contact layer is the other one of the n-type contact layer and the p-type contact layer.

15. The semiconductor device of claim 13, further comprising:
a first cladding layer located between the first contact layer and the first guiding layer.

16. The semiconductor device of claim 15, further comprising:
a second cladding layer located between the first cladding layer and the second contact layer.

17. The semiconductor device of claim 16, wherein the first contact layer, the first cladding layer, the first guiding layer, the second guiding layer, the photonic crystal layer, the second cladding layer and the second contact layer are made of homogeneous materials.

18. The semiconductor device of claim 13, wherein the second electrode is in contact with the second contact layer, and a width of the second electrode in contact with the second contact layer is less than a width of the photonic crystal layer.

19. The semiconductor device of claim 13, wherein each of the microstructures has a bottom and a protruding portion, wherein the protruding portions are disposed on the bottoms, and a projected area of the protruding portions on the bottoms is less than a projected area of the bottoms.

20. The semiconductor device of claim 19, wherein the bottoms are square or hexagonal, and the protruding portions are circle, square, rectangular, or a combination thereof.
